(19) United States
(12) Patent Application Publication
(10) Pub. No.: US 2023/0046682 A1
(43) Pub. Date: Feb. 16, 2023

(54) MASK DEFECT DETECTION

(71) Applicant: ASML Netherlands B.V., Veldhoven (NL)

(72) Inventors: Fuming WANG, Santa Clara, CA (US); Marco Jan-Jaco WIELAND, Delft (NL); Yu CAO, Saratoga, CA (US); Guohong ZHANG, Pleasanton, CA (US)

(21) Appl. No.: 17/886,348

(22) Filed: Aug. 11, 2022

Related U.S. Application Data
(60) Provisional application No. 63/232,135, filed on Aug. 11, 2021.

(51) Int. Cl. G03F 1/86; G03F 7/20

(52) U.S. Cl. CPC G03F 1/86; G03F 7/7065; G03F 7/70666

(57) ABSTRACT

An improved methods and systems for detecting defect(s) on a mask are disclosed. An improved method comprises inspecting an exposed wafer after the wafer was exposed, by a lithography system using a mask, with a selected process condition that is determined based on a mask defect printability under the selected process condition; and identifying, based on the inspection, a wafer defect that is caused by a defect on the mask to enable identification of the defect on the mask.

### CROSS-REFERENCE TO RELATED APPLICATIONS

This application claims priority of Provisional Application No. 63/232,135, filed on Aug. 11, 2021, which is incorporated herein by reference in its entirety.

### TECHNICAL FIELD

The embodiments provided herein relate to a mask qualification technology, and more particularly to an efficient mask defect detection mechanism using a charged-particle beam inspection system.

### BACKGROUND

A lithographic apparatus can be used, for example, in the manufacturing of integrated circuits (ICs). In such a case, a mask or a reticle may contain or provide a circuit pattern corresponding to an individual layer of the IC (“design layout”), and this circuit pattern can be transferred onto a target portion (e.g., comprising one or more dies) on a substrate (e.g., silicon wafer). Mask defects can greatly impact a process yield. Therefore, a mask status can be monitored by inspecting printed wafers to identify a mask defect and to identify when to take appropriate procedures when a mask defect is identified.

Inspection systems utilizing optical microscopes or charged particle (e.g., electron) beam microscopes, such as a scanning electron microscope (SEM) can be employed to locate a defect(s) on a mask based on inspection of printed wafers, which is referred to as a “print check” or “reticle print verification.” Due to stochastic properties, some mask defects including particle defects caused by external particles may not be printed on a wafer consistently, and thus a plurality of wafer fields would need to be inspected to capture all mask defects. However, inspecting two or more wafer fields with a SEM tool can be costly. Therefore, improving a mask defect detection performance is desired.

### SUMMARY

The embodiments provided herein disclose a particle beam inspection apparatus, and more particularly, an inspection apparatus using a plurality of charged-particle beams.

Some embodiments provide a method comprising: inspecting an exposed wafer after the wafer was exposed, by a lithography system using a mask, with a selected process condition that is determined based on a mask defect printability under the selected process condition; and identifying, based on the inspection, a wafer defect that is caused by a defect on the mask to enable identification of the defect on the mask.

Some embodiments provide a method for determining a modulation condition. The method comprises inspecting a plurality of multiple fields of a test wafer to identify a defect on a corresponding field after each of the multiple fields of the test wafer was exposed, by a lithography system using a mask, with a different process condition; and determining a modulation condition based on the inspection.

Some embodiments provide a method for determining a modulation condition. The method comprises setting a lithography model for simulating an exposure process of a wafer with a mask having a defect particle; simulating an electromagnetic field near the mask based on topography of the mask and the defect particle on the mask, the electromagnetic field enabling a determination of a light path near the mask; simulating an aerial image or resist image based on the simulated electromagnetic field at the wafer; and determining a modulation condition for a lithography system based on the simulated aerial image or resist image.

Some embodiments provide a charged particle beam device configured to inspect a wafer exposed by a lithography system using a mask. The device comprises a charged particle beam source configured to irradiate a first field and a second field of the wafer, the first field being exposed with a first process condition and the second field being exposed with a second process condition that is different from the first process condition; a detector configured to collect secondary charged particles emitted from the wafer that enable identification of a defect on the wafer, wherein the first field and the second field comprise a different number of defects on the corresponding field from each other; and a processor configured to facilitate a determination of a process condition to use to inspect a second mask based on mask defect printability, the mask defect printability being determined based on the identified defects.

Some embodiments provide an apparatus comprising a memory storing a set of instructions; and at least one processor configured to execute the set of instructions to cause the apparatus to perform: inspecting an exposed wafer after the wafer was exposed, by a lithography system using a mask, with a selected process condition that is determined based on a mask defect printability under the selected process condition; and identifying, based on the inspection, a wafer defect that is caused by a defect on the mask to enable identification of the defect on the mask.

Some embodiments provide an apparatus for determining a modulation condition, comprising: a memory storing a set of instructions; and at least one processor configured to execute the set of instructions to cause the apparatus to perform: inspecting a plurality of multiple fields of a test wafer to identify a defect on a corresponding field after each of the multiple fields of the test wafer was exposed, by a lithography system using a mask, with a different process condition; and determining a modulation condition based on the inspection.

Some embodiments provide an apparatus for determining a modulation condition, comprising: a memory storing a set of instructions; and at least one processor configured to execute the set of instructions to cause the apparatus to perform: setting a lithography model for simulating an exposure process of a wafer with a mask having a defect particle; simulating an electromagnetic field near the mask based on topography of the mask and the defect particle on the mask, the electromagnetic field enabling a determination of a light path near the mask; simulating an aerial image or resist image based on the simulated electromagnetic field at the wafer; and determining a modulation condition for a lithography system based on the simulated aerial image or resist image.

Some embodiments provide a non-transitory computer readable medium that stores a set of instructions that is executable by at least on processor of a computing device to cause the computing device to perform a method comprising: inspecting an exposed wafer after the wafer was exposed, by a lithography system using a mask, with a selected process condition that is determined based on a mask defect printability under the selected process condition; and identifying, based on the inspection, a wafer defect that is caused by a defect on the mask to enable identification of the defect on the mask.

Some embodiments provide a non-transitory computer readable medium that stores a set of instructions that is executable by at least on processor of a computing device to cause the computing device to perform a method for determining a modulation condition. The method comprises inspecting a plurality of multiple fields of a test wafer to identify a defect on a corresponding field after each of the multiple fields of the test wafer was exposed, by a lithography system using a mask, with a different process condition; and determining a modulation condition based on the inspection.

Some embodiments provide a non-transitory computer readable medium that stores a set of instructions that is executable by at least on processor of a computing device to cause the computing device to perform a method for determining a modulation condition. The method comprises setting a lithography model for simulating an exposure process of a wafer with a mask having a defect particle; simulating an electromagnetic field near the mask based on topography of the mask and the defect particle on the mask, the electromagnetic field enabling a determination of a light path near the mask; simulating an aerial image or resist image based on the simulated electromagnetic field at the wafer; and determining a modulation condition for a lithography system based on the simulated aerial image or resist image.

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

The above and other aspects of the present disclosure will become more apparent from the description of exemplary embodiments, taken in conjunction with the accompanying drawings.

FIG. 1 is a schematic block diagram of various subsystems of a lithography system, consistent with embodiments of the present disclosure.

FIG. 2 illustrate an exposed wafer having a plurality of fields, consistent with embodiments of the present disclosure.

FIG. 3A is a schematic diagram illustrating an example charged-particle beam inspection system, consistent with embodiments of the present disclosure.

FIG. 3B is a schematic diagram illustrating an example multi-beam tool that can be a part of the example charged-particle beam inspection system of FIG. 3A, consistent with embodiments of the present disclosure.

FIG. 4 is an example graph illustrating a defect printability and a defect detectability, consistent with embodiments of the present disclosure.

FIG. 5 is a block diagram of an example mask defect detection system, consistent with embodiments of the present disclosure.

FIG. 6A is an example graph illustrating an impact of a dose modulation on a critical dimension printed on a wafer, consistent with embodiments of the present disclosure.

FIG. 6B is an example graph illustrating a defect printability according to a dose modulation and a particle size, consistent with embodiments of the present disclosure.

FIG. 6C is an example defect printability process window according to a focus and exposure dose modulation, consistent with embodiments of the present disclosure.

FIG. 6D in an example graph illustrating an impact of an exposure dose modulation on a defect printability at fixed focus, consistent with embodiments of the present disclosure.

FIG. 7A illustrates an example process of determining a modulation condition based on experimentation, consistent with embodiments of the present disclosure.

FIG. 7B illustrates an example process of determining a modulation condition based on simulation, consistent with embodiments of the present disclosure.

FIG. 7C illustrates an example software platform for mask defect printability simulation, consistent with embodiments of the present disclosure.

FIG. 8 illustrates an example wafer having multiple fields, consistent with embodiments of the present disclosure.

FIG. 9 is a process flowchart representing an exemplary mask defect detection method, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can be fit on the substrate. For example, an IC chip in a smartphone can be as small as a thumbnail and yet may include over 2 billion transistors, the size of each transistor being less than ⅟1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection can be carried out using a scanning charged-particle microscope (SCPM). For example, an SCPM may be a scanning electron microscope (SEM). A SCPM can be used to image these extremely small structures, in effect, taking a “picture” of the structures of the wafer. The image can be used to determine if the structure was formed properly in the proper location. If the structure is defective, then the process can be adjusted, so the defect is less likely to recur. As the physical sizes of IC components continue to shrink, accuracy and yield in defect detection become more important. Inspection images such as SEM images can be used to identify or classify a defect(s) of the manufactured ICs.

A lithographic apparatus can be used, for example, in the manufacturing of integrated circuits (ICs). In such a case, a mask or a reticle may contain or provide a circuit pattern corresponding to an individual layer of the IC (“design layout”), and this circuit pattern can be transferred onto a target portion (e.g. comprising one or more dies) on a substrate (e.g., silicon wafer) that has been coated with a layer of radiation-sensitive material (“resist”), by methods such as irradiating the target portion through the circuit pattern on the mask. Mask defects can greatly impact a process yield. A mask status can be monitored by inspecting printed wafers to identify a mask defect and to take a proper follow-up procedure when a mask defect is identified. For example, procedures to remove the defect on the mask, e.g., by cleaning or reworking the mask, can be performed. As lithography moves into high volume manufacturing (HVM), locating and curing a defect(s) of a mask becomes more important.

In a print check methodology, a mask is used to form patterns on a wafer, and the wafer is inspected to detect a defect on the mask. For example, a wafer is inspected to locate a defect on the wafer, and the defect can be determined to be caused by a defect on the mask if the defect repeats at the same location on multiple wafer fields. Inspection images such as SEM images can also be used in the print check. While a print check is based on an assumption that a mask defect is repeatedly printed on a wafer, some mask defects including particle defects caused by external particles may not reliably be printed on a wafer due to stochasticity. External particles can be generated in various IC manufacturing processes or in radiation generating processes. For example, a certain particle on a mask may be printed in one wafer field but not in another wafer field. For instance, a 60 nm particle on a mask may only be printed about 10% of the time due to stochastic properties of radiation that is applied to the mask to form the pattern on the wafer. Therefore, a plurality of wafer fields would need to be fully inspected to capture all mask defects. However, fully inspecting multiple wafer fields with a SEM tool can take a long time, which can lead to overall throughput degradation. Therefore, improving a mask defect detection performance is desired.

Embodiments of the disclosure can provide a mechanism for improving a mask defect printability on a wafer. According to some embodiments of the present disclosure, a mask defect printability can be improved by modulating a process condition when exposing a wafer with a mask. According to some embodiments of the present disclosure, a full inspection of one or more wafer fields can identify a potential mask defect(s) including a particle defect(s). According to some embodiments of the present disclosure, the potential mask defect(s) can be verified whether the defect is a mask defect or not by performing a spot inspection on another wafer field. Embodiments of the present disclosure can provide a mechanism for determining a process condition for tuning based on experimentation or simulation.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

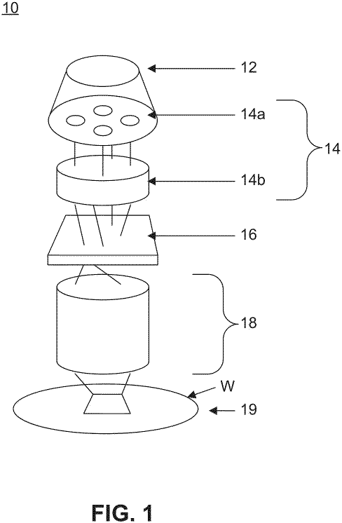

FIG. 1 is a schematic block diagram of various subsystems of a lithography system, consistent with embodiments of the present disclosure. As shown in FIG. 1, a lithography system 10 can comprise an illumination source 12, illumination optics 14, a mask 16 (or a reticle), and transmission optics 18. Illumination source 12 may be a deep-ultraviolet excimer laser source or other type of sources including extreme ultra violet (EUV) sources. Illumination optics 14 may define the partial coherence and may include optics 14a and 14b that shape radiation from illumination source 12. Transmission optics 18 can project an image of a mask pattern onto a substrate plane 19. An adjustable filter or aperture at the pupil plane of projection optics 18 may restrict the range of beam angles that impinge on the substrate plane 19.

In a lithographic apparatus, illumination source 12 provides illumination (i.e., radiation) to mask 16; projection optics direct and shapes the illumination, via mask 16, onto a substrate W. The term “projection optics” is broadly defined here to include any optical component that may alter the wavefront of the radiation beam. For example, projection optics may include at least some of illumination optics 14 and transmission optics 18.

Although specific reference may be made in this text to the use of the embodiments in the manufacture of ICs, it should be explicitly understood that the embodiments have many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle,” “wafer” or “field” in this text should be considered as interchangeable with the more general terms “mask,” “substrate” and “target portion,” respectively. In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range 5-20 nm).

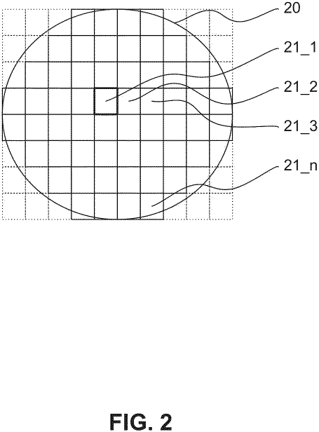

FIG. 2 illustrate an exposed wafer having a plurality of fields, consistent with embodiments of the present disclosure. As shown in FIG. 2, a wafer 20 can contain a plurality of fields 21_1 to 21_n each corresponding to an area of a mask (e.g., mask 16 of FIG. 1). In some embodiments, a mask is used to produce a circuit pattern to each of a plurality of fields 21_1 to 21_n. In some embodiments, a mask is used to successively produce a circuit pattern onto a plurality of fields 21_1 to 21_n by a lithography system (e.g., lithography system of FIG. 1). In some embodiments, each field can comprise one die or any number of dies. In one type of lithographic apparatuses, the circuit pattern from the entire mask is transferred onto one field in one go; such an apparatus is commonly referred to as a stepper. In an alternative apparatus, commonly referred to as a step-and-scan apparatus, a projection beam scans over the mask in a given reference direction (the “scanning” direction). Different portions of the circuit pattern on the mask are transferred to one field progressively. In some embodiments, wafer 20 is inspected by a SEM tool to locate a defect on the mask by inspecting one or more fields 21_1 to 21_n.

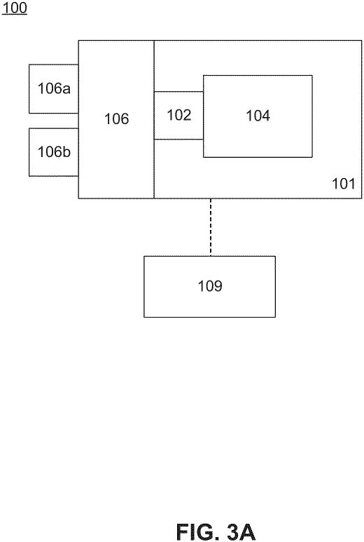

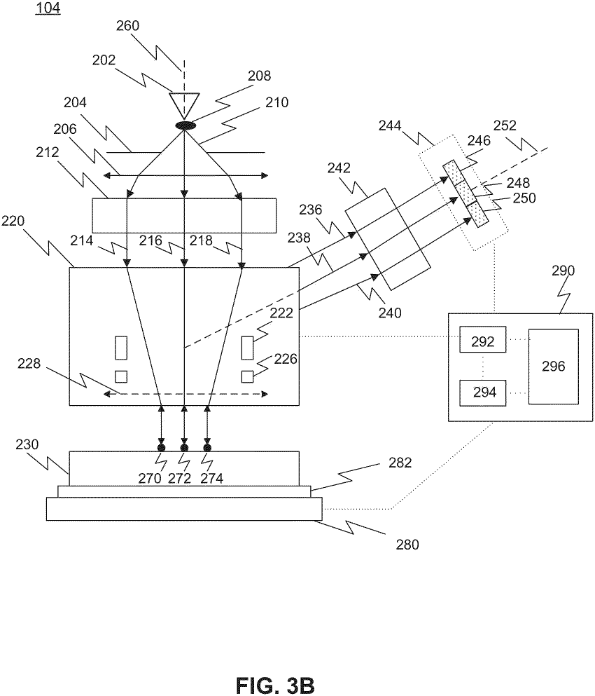

FIG. 3A illustrates an example electron beam inspection (EBI) system 100 consistent with embodiments of the present disclosure. EBI system 100 may be used for imaging. As shown in FIG. 3A, EBI system 100 includes a main chamber 101, a load/lock chamber 102, abeam tool 104, and an equipment front end module (EFEM) 106. Beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer configured to execute various controls of EBI system 100. While controller 109 is shown in FIG. 3A as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes and data may include an operating system (OS) and one or more application programs (or “apps”) for specific tasks. The memory may also be a virtual memory that includes one or more memories distributed across multiple machines or devices coupled via a network.

FIG. 3B illustrates a schematic diagram of an example multi-beam tool 104 (also referred to herein as apparatus 104) and an image processing system 290 that may be configured for use in EBI system 100 (FIG. 3A), consistent with embodiments of the present disclosure.

Beam tool 104 comprises a charged-particle source 202, a gun aperture 204, a condenser lens 206, a primary charged-particle beam 210 emitted from charged-particle source 202, a source conversion unit 212, a plurality of beamlets 214, 216, and 218 of primary charged-particle beam 210, a primary projection optical system 220, a motorized wafer stage 280, a wafer holder 282, multiple secondary charged-particle beams 236, 238, and 240, a secondary optical system 242, and a charged-particle detection device 244. Primary projection optical system 220 can comprise a beam separator 222, a deflection scanning unit 226, and an objective lens 228. Charged-particle detection device 244 can comprise detection sub-regions 246, 248, and 250.

Charged-particle source 202, gun aperture 204, condenser lens 206, source conversion unit 212, beam separator 222, deflection scanning unit 226, and objective lens 228 can be aligned with a primary optical axis 260 of apparatus 104. Secondary optical system 242 and charged-particle detection device 244 can be aligned with a secondary optical axis 252 of apparatus 104.

Charged-particle source 202 can emit one or more charged particles, such as electrons, protons, ions, muons, or any other particle carrying electric charges. In some embodiments, charged-particle source 202 may be an electron source. For example, charged-particle source 202 may include a cathode, an extractor, or an anode, wherein primary electrons can be emitted from the cathode and extracted or accelerated to form primary charged-particle beam 210 (in this case, a primary electron beam) with a crossover (virtual or real) 208. For ease of explanation without causing ambiguity, electrons are used as examples in some of the descriptions herein. However, it should be noted that any charged particle may be used in any embodiment of this disclosure, not limited to electrons. Primary charged-particle beam 210 can be visualized as being emitted from crossover 208. Gun aperture 204 can block off peripheral charged particles of primary charged-particle beam 210 to reduce Coulomb effect. The Coulomb effect may cause an increase in size of probe spots.

Source conversion unit 212 can comprise an array of image-forming elements and an array of beam-limit apertures. The array of image-forming elements can comprise an array of micro-deflectors or micro-lenses. The array of image-forming elements can form a plurality of parallel images (virtual or real) of crossover 208 with a plurality of beamlets 214, 216, and 218 of primary charged-particle beam 210. The array of beam-limit apertures can limit the plurality of beamlets 214, 216, and 218. While three beamlets 214, 216, and 218 are shown in FIG. 3B, embodiments of the present disclosure are not so limited. For example, in some embodiments, the apparatus 104 may be configured to generate a first number of beamlets. In some embodiments, the first number of beamlets may be in a range from 1 to 1000. In some embodiments, the first number of beamlets may be in a range from 200-500. In an exemplary embodiment, an apparatus 104 may generate 400 beamlets.

Condenser lens 206 can focus primary charged-particle beam 210. The electric currents of beamlets 214, 216, and 218 downstream of source conversion unit 212 can be varied by adjusting the focusing power of condenser lens 206 or by changing the radial sizes of the corresponding beam-limit apertures within the array of beam-limit apertures. Objective lens 228 can focus beamlets 214, 216, and 218 onto a wafer 230 for imaging, and can form a plurality of probe spots 270, 272, and 274 on a surface of wafer 230.

Beam separator 222 can be a beam separator of Wien filter type generating an electrostatic dipole field and a magnetic dipole field. In some embodiments, if they are applied, the force exerted by the electrostatic dipole field on a charged particle (e.g., an electron) of beamlets 214, 216, and 218 can be substantially equal in magnitude and opposite in a direction to the force exerted on the charged particle by magnetic dipole field. Beamlets 214, 216, and 218 can, therefore, pass straight through beam separator 222 with zero deflection angle. However, the total dispersion of beamlets 214, 216, and 218 generated by beam separator 222 can also be non-zero. Beam separator 222 can separate secondary charged-particle beams 236, 238, and 240 from beamlets 214, 216, and 218 and direct secondary charged-particle beams 236, 238, and 240 towards secondary optical system 242.

Deflection scanning unit 226 can deflect beamlets 214, 216, and 218 to scan probe spots 270, 272, and 274 over a surface area of wafer 230. In response to the incidence of beamlets 214, 216, and 218 at probe spots 270, 272, and 274, secondary charged-particle beams 236, 238, and 240 may be emitted from wafer 230. Secondary charged-particle beams 236, 238, and 240 may comprise charged particles (e.g., electrons) with a distribution of energies. For example, secondary charged-particle beams 236, 238, and 240 may be secondary electron beams including secondary electrons (energies ≤ 50 eV) and backscattered electrons (energies between 50 eV and landing energies of beamlets 214, 216, and 218). Secondary optical system 242 can focus secondary charged-particle beams 236, 238, and 240 onto detection sub-regions 246, 248, and 250 of charged-particle detection device 244. Detection sub-regions 246, 248, and 250 may be configured to detect corresponding secondary charged-particle beams 236, 238, and 240 and generate corresponding signals (e.g., voltage, current, or the like) used to reconstruct an SCPM image of structures on or underneath the surface area of wafer 230.

The generated signals may represent intensities of secondary charged-particle beams 236, 238, and 240 and may be provided to image processing system 290 that is in communication with charged-particle detection device 244, primary projection optical system 220, and motorized wafer stage 280. The movement speed of motorized wafer stage 280 may be synchronized and coordinated with the beam deflections controlled by deflection scanning unit 226, such that the movement of the scan probe spots (e.g., scan probe spots 270, 272, and 274) may orderly cover regions of interests on the wafer 230. The parameters of such synchronization and coordination may be adjusted to adapt to different materials of wafer 230. For example, different materials of wafer 230 may have different resistance-capacitance characteristics that may cause different signal sensitivities to the movement of the scan probe spots.

The intensity of secondary charged-particle beams 236, 238, and 240 may vary according to the external or internal structure of wafer 230, and thus may indicate whether wafer 230 includes defects. Moreover, as discussed above, beamlets 214, 216, and 218 may be projected onto different locations of the top surface of wafer 230, or different sides of local structures of wafer 230, to generate secondary charged-particle beams 236, 238, and 240 that may have different intensities. Therefore, by mapping the intensity of secondary charged-particle beams 236, 238, and 240 with the areas of wafer 230, image processing system 290 may reconstruct an image that reflects the characteristics of internal or external structures of wafer 230.

In some embodiments, image processing system 290 may include an image acquirer 292, a storage 294, and a controller 296. Image acquirer 292 may comprise one or more processors. For example, image acquirer 292 may comprise a computer, server, mainframe host, terminals, personal computer, any kind of mobile computing devices, or the like, or a combination thereof. Image acquirer 292 may be communicatively coupled to charged-particle detection device 244 of beam tool 104 through a medium such as an electric conductor, optical fiber cable, portable storage media, IR, Bluetooth, internet, wireless network, wireless radio, or a combination thereof. In some embodiments, image acquirer 292 may receive a signal from charged-particle detection device 244 and may construct an image. Image acquirer 292 may thus acquire scanning charged-particle microscope (SCPM) images of wafer 230. Image acquirer 292 may also perform various post-processing functions, such as generating contours, superimposing indicators on an acquired image, or the like. Image acquirer 292 may be configured to perform adjustments of brightness and contrast of acquired images. In some embodiments, storage 294 may be a storage medium such as a hard disk, flash drive, cloud storage, random access memory (RAM), other types of computer-readable memory, or the like. Storage 294 may be coupled with image acquirer 292 and may be used for saving scanned raw image data as original images, and post-processed images. Image acquirer 292 and storage 294 may be connected to controller 296. In some embodiments, image acquirer 292, storage 294, and controller 296 may be integrated together as one control unit.

In some embodiments, image acquirer 292 may acquire one or more SCPM images of a wafer based on an imaging signal received from charged-particle detection device 244. An imaging signal may correspond to a scanning operation for conducting charged particle imaging. An acquired image may be a single image comprising a plurality of imaging areas. The single image may be stored in storage 294. The single image may be an original image that may be divided into a plurality of regions. Each of the regions may comprise one imaging area containing a feature of wafer 230. The acquired images may comprise multiple images of a single imaging area of wafer 230 sampled multiple times over a time sequence. The multiple images may be stored in storage 294. In some embodiments, image processing system 290 may be configured to perform image processing steps with the multiple images of the same location of wafer 230.

In some embodiments, image processing system 290 may include measurement circuits (e.g., analog-to-digital converters) to obtain a distribution of the detected secondary charged particles (e.g., secondary electrons). The charged-particle distribution data collected during a detection time window, in combination with corresponding scan path data of beamlets 214, 216, and 218 incident on the wafer surface, can be used to reconstruct images of the wafer structures under inspection. The reconstructed images can be used to reveal various features of the internal or external structures of wafer 230, and thereby can be used to reveal any defects that may exist in the wafer.

In some embodiments, the charged particles may be electrons. When electrons of primary charged-particle beam 210 are projected onto a surface of wafer 230 (e.g., probe spots 270, 272, and 274), the electrons of primary charged-particle beam 210 may penetrate the surface of wafer 230 for a certain depth, interacting with particles of wafer 230. Some electrons of primary charged-particle beam 210 may elastically interact with (e.g., in the form of elastic scattering or collision) the materials of wafer 230 and may be reflected or recoiled out of the surface of wafer 230. An elastic interaction conserves the total kinetic energies of the bodies (e.g., electrons of primary charged-particle beam 210) of the interaction, in which the kinetic energy of the interacting bodies does not convert to other forms of energy (e.g., heat, electromagnetic energy, or the like). Such reflected electrons generated from elastic interaction may be referred to as backscattered electrons (BSEs). Some electrons of primary charged-particle beam 210 may inelastically interact with (e.g., in the form of inelastic scattering or collision) the materials of wafer 230. An inelastic interaction does not conserve the total kinetic energies of the bodies of the interaction, in which some or all of the kinetic energy of the interacting bodies convert to other forms of energy. For example, through the inelastic interaction, the kinetic energy of some electrons of primary charged-particle beam 210 may cause electron excitation and transition of atoms of the materials. Such inelastic interaction may also generate electrons exiting the surface of wafer 230, which may be referred to as secondary electrons (SEs). Yield or emission rates of BSEs and SEs depend on, e.g., the material under inspection and the landing energy of the electrons of primary charged-particle beam 210 landing on the surface of the material, among others. The energy of the electrons of primary charged-particle beam 210 may be imparted in part by its acceleration voltage (e.g., the acceleration voltage between the anode and cathode of charged-particle source 202 in FIG. 3B). The quantity of BSEs and SEs may be more or fewer (or even the same) than the injected electrons of primary charged-particle beam 210.

The images generated by SEM may be used for defect inspection. For example, a generated image capturing a test device region of a wafer may be compared with a reference image capturing the same test device region. The reference image may be predetermined (e.g., by simulation) and include no known defect. If a difference between the generated image and the reference image exceeds a tolerance level, a potential defect may be identified. For another example, the SEM may scan multiple regions of the wafer, each region including a test device region designed as the same, and generate multiple images capturing those test device regions as manufactured. The multiple images may be compared with each other. If a difference between the multiple images exceeds a tolerance level, a potential defect may be identified.

In some embodiments, a SEM image can also be utilized to locate a mask defect by inspecting one or more fields, e.g., 21_1 to 21_n in FIG. 2. When a defect repeats on multiple fields 21_1 to 21_n, the defect can be considered as a mask defect. However, some mask defects including particle defects caused by external particles may not be printed in every field due to stochastic properties of radiation that is applied to the mask to form the pattern on the wafer. For example, a certain particle on a mask can be printed as a defect in one field but not in another field. Therefore, to capture all mask defects, a plurality of fields may be inspected. For example, a certain size of a particle on a mask may be printed only about 10% of the time. Accordingly, in such a scenario, a large number of fields on the wafer would need to be inspected to capture all mask defects including particle defects, thereby lowering throughput on mask defect detection.

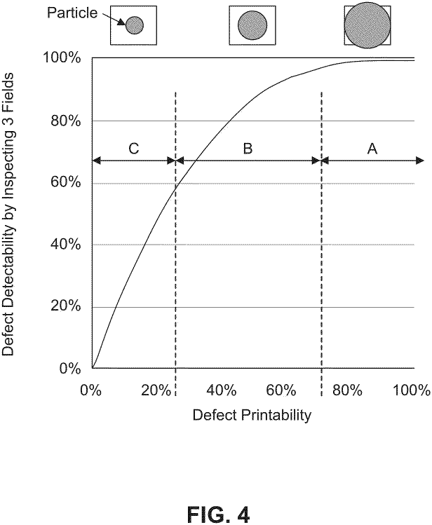

FIG. 4 is an example graph illustrating a defect printability and a defect detectability, consistent with embodiments of the present disclosure. In FIG. 4, defect(s) that are printed in a field with probability 75% to 100% are grouped as a first group A, defect(s) that are printed in a field with probability 25% to 75% are grouped as a second group B, and defect(s) that are printed in a field with probability less than 25% are grouped as a third group C. FIG. 4 also illustrates defect printability strength per particle size as an example factor. It will be noted from FIG. 4 that a defect printability can decrease as a particle size shrinks. As shown in FIG. 4, almost all defect(s) in first group A can be detected by inspecting 3 fields, about 60 to 95% of defect(s) in second group B can be detected by inspecting 3 fields, and less than 60% of defect(s) in third group C can be detected by inspecting 3 fields. It will be noted that in order to detect all mask defect(s) in second group B or third group C, more than 3 fields may be inspected.

As the physical sizes of IC components continue to shrink, accuracy and yield in defect detection become more important. A pixel size of a SEM image keeps decreasing to maintain a certain level of defect sensitivity and a resolution. Therefore, inspecting multiple fields with a SEM tool can take a long time, which can ultimately degrade an overall yield. Embodiments of the present disclosure can provide a mask defect detection system that can detect mask defect(s) including particle defect(s) based on a full inspection of one field. According to some embodiments of the present disclosure, a mask defect can reliably be printed on a wafer by modulating a process condition for exposing a wafer with a lithography system.

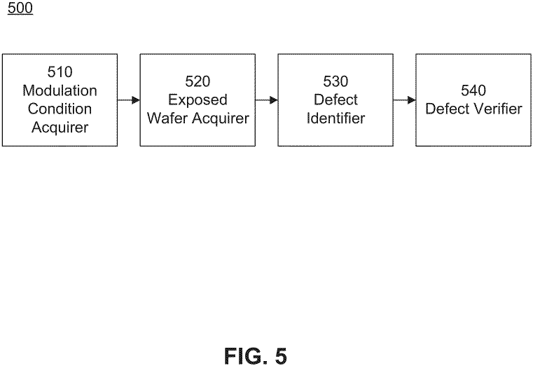

Reference is now made to FIG. 5, which is a block diagram of an example mask defect detection system, consistent with embodiments of the present disclosure. In some embodiments, a mask defect detection system 500 can comprise one or more processors and memories. It is appreciated that in various embodiments mask defect detection system 500 may be part of or may be separate from a charged-particle beam inspection system (e.g., EBI system 100 of FIG. 3A), or computational lithography system, or other photolithography systems. In some embodiments, mask defect detection system 500 may include one or more components (e.g., software modules) that can be implemented in controller 109 as discussed herein. As shown in FIG. 5, mask defect detection system 500 may comprise a modulation condition acquirer 510, an exposed wafer acquirer 520, a defect identifier 530, and a defect verifier 540.

According to some embodiments of the present disclosure, modulation condition acquirer 510 can acquire a modulation process condition that can be used to expose a wafer with a lithography system. In some embodiments, a modulation condition can enhance a mask defect printability on the wafer. In some embodiments, a modulation condition can cause a mask defect(s) including a particle defect(s) on a mask can more reliably be printed on a wafer, thereby improving a mask defect detection rate. In some embodiments, when an external particle partially blocks a pattern on a mask, the particle can cause the pattern printed on a wafer to be shrunken or expanded rather than the particle is printed as a hard defect on a wafer. If this size change of a printed pattern is out of a defect detection sensitivity range of a SEM tool, an inspection of the printed pattern may not capture the particle defect. According to some embodiments of the present disclosure, a modulation process condition can be selected to boost a defect printability such that a mask defect(s) including a particle defect(s) is printed as a hard defect on a wafer. In some embodiments, a modulation process condition can be different from a nominal process condition. In some embodiments, nominal process condition can be a production process condition of a lithography system for exposing a wafer with a mask for production. In some embodiments, the most probable process condition can be often defined as a nominal process condition under which acceptable wafer quality is desired with minimizing variations between different fields or wafers. In some embodiments, a nominal process condition can be an optimal process condition suitable for printing wafers for high volume manufacturing (HVM).

According to some embodiments of the present disclosure, a process condition that can be tuned to improve a defect printability can comprise exposure dose, focus, an illumination condition, etc. of a lithography system, e.g., lithography system 10 of FIG. 1. In some embodiments, exposure dose can indicate how much light or radiation to let through and can be defined as the light intensity multiplied by the exposure time as units of energy density mJ/cm². In some embodiments, exposure dose can be modulated, among others, by controlling operation of illumination source 12 of lithography system 10. In some embodiments, focus can indicate a focus point of transmission optics 18 relative to substrate plane 19. In some embodiments, focus can be modulated, among others, by controlling operation of transmission optics 18. In some embodiments, focus can be modulated by controlling operation of components such as filters, lenses, etc. of transmission optics 18.

In some embodiments, an illumination condition can indicate a characteristic(s) of radiation incident on a mask from illumination source 12. A characteristic(s) of radiation can represent how radiation is incident on a mask. In some embodiments, an illumination condition can comprise, but is not limited to, a radiation incident angle on a mask, a radiation pattern on a mask, a number of radiation beams incident on a mask, etc. In some embodiments, an illumination condition can be modulated, among others, by controlling operation of illumination optics 14 of lithography system 10. In some embodiments, illumination optics 14 can comprise various components such as filters, lenses, mirrors, etc., and such various components can be used to precisely condition the radiation beam incident on a mask to have a desired property. In some embodiments, an illumination condition can be modulated by controlling illumination pupils of illumination optics 14. In some embodiments, illumination pupils can be implemented as a facetted pupil mirror array. In some embodiments, an illumination condition can be modulated by adjusting a number of pupils, a reflection angle of each pupil, a radiation pattern coming out of pupils, etc.

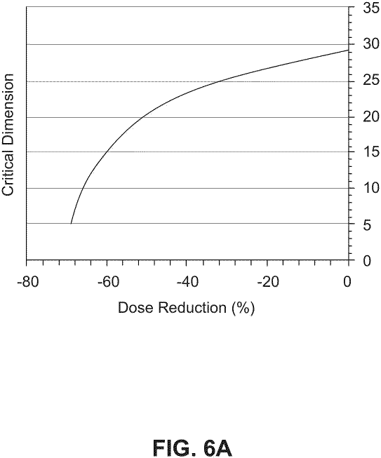

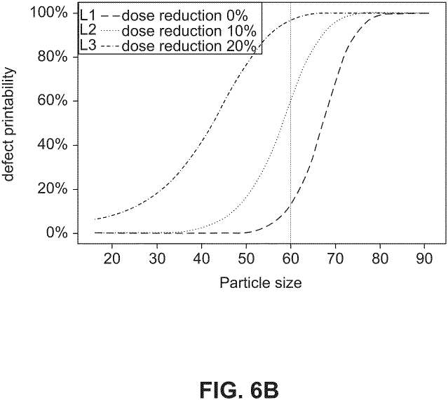

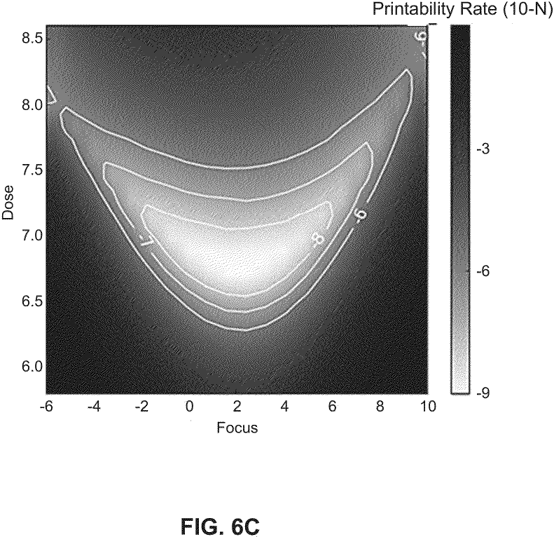

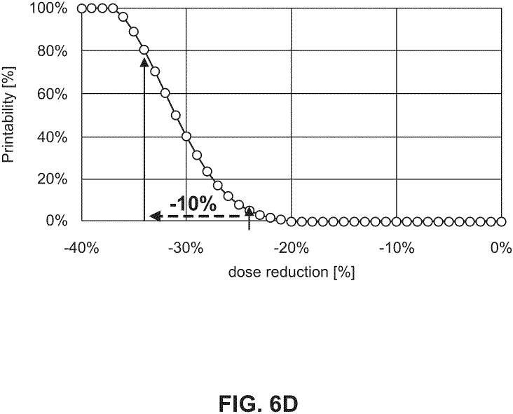

FIG. 6A is an example graph illustrating an impact of a dose modulation on a critical dimension printed on a wafer, consistent with embodiments of the present disclosure. FIG. 6A illustrates how a critical dimension of a certain structure printed on a wafer changes as exposure dose decreases when a particle(s) exists on a mask corresponding to the certain structure. For example, the structure can be a contact hole and a critical dimension of the contact hole can be measured by a diameter of the contact hole. In FIG. 6A, a critical dimension of a structure measured on a wafer becomes smaller as exposure dose used for exposing the wafer decreases. For example, when exposure dose is reduced by 60% (indicated as -60% on a horizontal axis at the bottom in FIG. 6A) from nominal exposure dose (indicated as 0% on a horizontal axis at the bottom in FIG. 6A), a critical dimension decreases by about 45%. When a critical dimension change enters a defect detection sensitivity range of a SEM tool, the particle on a mask can be detected as a hard defect on a printed wafer. It will be noted from FIG. 6A that an impact of a particle(s) that blocks lights on a mask can be stronger when exposure dose is modulated, which can increase a defect printability such that a mask defect(s) including a particle defect(s) is printed as a hard defect. As shown in FIG. 6A, by modulating exposure dose, a defect printability and accordingly a defect detectability can be improved.

FIG. 6B is an example graph illustrating a defect printability according to a dose modulation and a particle size, consistent with embodiments of the present disclosure. In FIG. 6B, a first line L1 shows how a defect printability changes according to a particle size when there is no dose modulation, a second line L2 shows how a defect printability changes according to a particle size when there is 10% dose reduction from nominal dose, and a third line L3 shows how a defect printability changes according to a particle size when there is 20% dose reduction from nominal dose. It will be noted by a vertical dotted line at particle size 60 in FIG. 6B, a defect printability of a same particle size can increase as exposure dose decreases. It will also be noted from FIG. 6B that a defect printability can increase as a particle size becomes bigger. According to some embodiments of the present disclosure, an impact of exposure dose modulation can be different per particle size. It will be appreciated that numerical values for particle sizes or critical dimensions of the present disclosure are used to show a ratio between different particle sizes or critical dimensions rather than exact values.

FIG. 6C is an example defect printability process window according to a focus and exposure dose modulation, consistent with embodiments of the present disclosure. In FIG. 6C, a focus change is indicated on a horizontal axis at the bottom, an exposure dose change is indicated on a vertical axis at the left side, and a defect printability change according to a focus and exposure dose change is indicated as a contrast level defined by a contrast bar at the right side. In FIG. 6C, a printability rate is indicated in a log scale, and all points on a connected white line have the same level of a printability rate. As shown in FIG. 6C, a focus modulation can also impact a defect printability in addition to an exposure dose modulation. It will be noted from FIG. 6C that an impact of a focus modulation on a defect printability can change depending on exposure dose and vice versa. It will also be appreciated that numerical values for exposure dose and focus of FIG. 6C are used to show a dose or focus level ratio rather than exact values.

FIG. 6D in an example graph illustrating an impact of an exposure dose modulation on a defect printability at fixed focus, consistent with embodiments of the present disclosure. FIG. 6D showshow a defect printability can change when exposure dose decreases from 0% to -40% at a certain focus level, e.g., focus value 2 in FIG. 6C. In FIG. 6D, it is noted that a defect printability can increase by about 80% by reducing exposure dose from -25% to -35%. It will be noted that, without a process condition modulation, a same level of a defect detection rate (e.g., 80%) can be achieved by inspecting about 32 full fields when each of those fields has approximately 5% defect printability.

According to some embodiments of the present disclosure, an illumination condition can also change a mask defect printability on a wafer. In some embodiments, a modulation of an illumination condition can affect the extent of an impact of an exposure dose or focus modulation on a defect printability. For example, by changing an illumination condition, the shape or a gradient of the graph in FIG. 6D can change. Therefore, when determining a modulation process condition, various process parameters can be considered together. While an impact of a modulation of exposure dose, focus, or an illumination condition on a defect printability has been explained, it will be appreciated that other process parameter(s) operating a lithography system can be utilized as a modulation parameter(s).

Referring back to FIG. 5, according to some embodiments of the present disclosure, modulation condition acquirer 510 can determine a modulation condition based on experimentation or simulation.

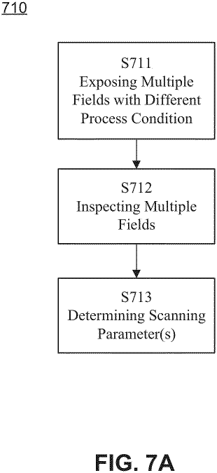

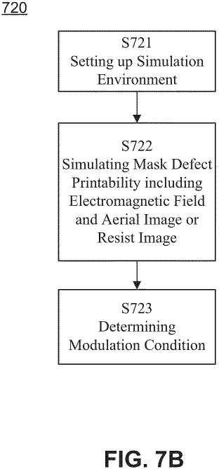

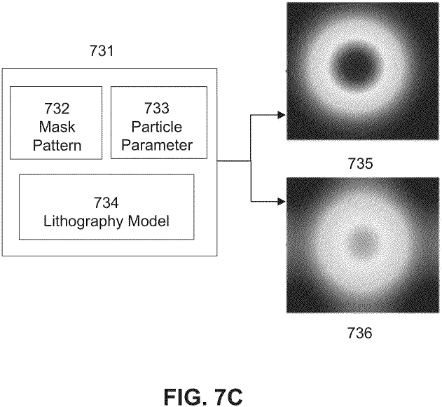

FIG. 7A illustrates an example process of determining a modulation condition based on experimentation, consistent with embodiments of the present disclosure. It is appreciated that the illustrated process 710 can be altered to modify the order of steps and to include additional steps.

In step S711, multiple fields can be exposed on a wafer with a different process condition. In some embodiments, step S711 can be performed by lithography system 10 in FIG. 1. In some embodiments, one mask pattern can be exposed multiple times with a different process condition. For example, referring to FIG. 2, a first field 21_1 can be exposed with a first process condition, a second field 21_2 can be exposed with a second process condition, and a n^{th} field 21_n can be exposed with a n^{th} process condition. In some embodiments, a process condition can comprise one process parameter, and each process condition can comprise a different process parameter value. In some embodiments, a process condition can comprise a plurality of process parameters, and each condition can comprise a different parameter value combination of a plurality of process parameters.

In step S712, multiple fields can be inspected to detect defect(s) on multiple fields. In some embodiments, step S712 can be performed by EBI system 100 of FIG. 3A or electron beam tool 104 of FIG. 3B. In some embodiments, an inspection to identify defect(s) can be performed on an entire area of a field. In some embodiments, an inspection can be performed on a partial area of a field. For example, a fraction (e.g., 1% area) of a field can be inspected to detect defect(s) on the corresponding field.

In step S713, a modulation condition can be determined based on inspection results on multiple fields. In some embodiments, a modulation condition can be a process condition set for exposing a selected field among multiple fields based on inspection results. In some embodiments, one field that meets a criterion can be selected among the inspected multiple fields based on inspection results. In some embodiments, a criterion can be a number of defects that are detected by an inspection. While a modulation condition can enhance a mask defect printability, a modulation of process parameter(s) can also increase other defect(s) on a printed wafer, which are not caused by a mask defect and can be referred to as a process defect. Therefore, in some embodiments, a criterion can be a number of defects that can be handled by defect verifier 540. For example, a field of which 1% area includes about 10 defects can be selected among the inspected multiple fields. In some embodiments, a process condition used for exposing the selected field can be selected to be a modulation condition.

FIG. 7B illustrates an example process of determining a modulation condition based on simulation, consistent with embodiments of the present disclosure. It is appreciated that the illustrated process 720 can be altered to modify the order of steps and to include additional steps.

In step S721, a simulation environment for simulating a mask defect printability can be setup. According to some embodiments of the present disclosure, a mask defect printability can be simulated without printing a mask pattern on a real wafer. In some embodiments, a mask defect printability simulation can be performed on a software platform such as Tachyon. FIG. 7C illustrates an example software platform for mask defect printability simulation, consistent with some embodiments of the present disclosure. As shown in FIG. 7C, software platform 731 can comprise a mask pattern 732, particle parameter(s) 733, and lithography model(s) 734 as a simulation environment.

In some embodiments, mask pattern 732 can be a pattern of a mask to be inspected. In some embodiments, mask pattern 732 can be a layout file for a wafer design corresponding to mask pattern 732. The layout file can be in a Graphic Database System (GDS) format, Graphic Database System II (GDS II) format, an Open Artwork System Interchange Standard (OASIS) format, a Caltech Intermediate Format (CIF), etc. The wafer design may include patterns or structures for inclusion on the wafer. The patterns or structures can be mask patterns used to transfer features from the photolithography masks or reticles to a wafer. In some embodiments, a layout in GDS or OASIS format, among others, may comprise feature information stored in a binary file format representing planar geometric shapes, text, and other information related to the wafer design.

According to some embodiments of the present disclosure, particle parameter(s) 733 can include, but is not limited to, a particle size, a particle location on a mask pattern (e.g., mask pattern 732), a particle material, a particle shape, etc. In some embodiments of the present disclosure, in step S721, particle parameter(s) 733 can be set up. According to some embodiments of the present disclosure, lithography model(s) 734 with a different process condition can be set up. In some embodiments, a process condition can comprise any one of exposure dose, focus, an illumination condition, etc. In some embodiments, each lithography model can comprise a different setting of a process condition.

In step S722, a mask defect printability can be simulated under a simulation environment set up in step S721. In some embodiments, a simulation can be performed for each lithography model with a corresponding process condition. In some embodiments, a simulation for a mask defect printability can include a simulation of an electromagnetic field near a mask. In some embodiments, an electromagnetic field near a mask can be simulated based on a mask topography, a particle location on a mask, a particle property, etc. In some embodiments, a particle property can include, but is not limited to, a size, a shape, a constituting material, etc. According to some embodiments of the present disclosure, an electromagnetic field near a mask can vary according to a mask topography and a particle property on the mask, which can enable a determination of behaviors of photons illuminating on the mask. An electromagnetic field distribution around external particle(s) on a mask can show impacts of the particle(s) on photons illuminating on the mask compared to a normal mask without the particle(s). According to some embodiments of the present disclosure, how a light path near a mask is altered or varied according to a mask topography and a particle property can be determined based on an electromagnetic field near a mask.

According to some embodiments of the present disclosure, in step S722, an aerial image or a resist image on a wafer can be simulated based on the simulated electromagnetic field. In a lithographic apparatus, an illumination source provides illumination (i.e., radiation) to a mask; projection optics direct and shapes the illumination, via the mask, onto a wafer. An aerial image (AI) is the radiation intensity distribution on the wafer. A resist layer on the wafer is exposed and the aerial image is transferred to the resist layer as a latent “resist image” (RI) therein. The resist image (RI) can be defined as a spatial distribution of solubility of the resist in the resist layer. A resist model can be used to calculate the resist image from the aerial image, an example of which can be found in commonly assigned U.S. Pat. Application Publication No. US 2009-0157360, the disclosure of which is hereby incorporated by reference in its entirety. The resist model is related only to properties of the resist layer (e.g., effects of chemical processes which occur during exposure, PEB and development). Optical properties of the lithographic apparatus (e.g., properties of the illumination, the mask, and the projection optics) dictate the aerial image. Since the mask used in the lithographic apparatus can be changed, it is desirable to separate the optical properties of the mask from the optical properties of the rest of the lithographic apparatus including at least the illumination and the projection optics.

According to some embodiments of the present disclosure, an aerial image or a resist image can also carry information of a particle(s) on a mask after light reflected off the mask. In some embodiments, a simulated aerial image can include the radiation intensity distribution, which exposes a resist layer on a wafer. FIG. 7C illustrates two aerial images 735 and 736 for a mask pattern generated by software platform 731 to show how a particle affects an aerial image as an example. In this example, aerial image 735 is generated when a particle is not present on a mask pattern, and aerial image 736 is generated when a particle is present on the same mask pattern. It is noted from FIG. 7C that a presence of a particle on a mask pattern may change the radiation intensity distribution on a wafer. In some embodiments, a mask defect printability can be analyzed based on aerial image(s). According to some embodiments of the present disclosure, a resist image can also be simulated by combining with a resist model, which can enable an accurate prediction of a mask defect printability on a wafer.

In step S723, a modulation condition can be determined based on simulation results for multiple lithography models. In some embodiments, a modulation condition can be a process condition set for a selected lithography model. In some embodiments, one lithography model that meets a criterion can be selected among the multiple lithography models. In some embodiments, one lithography model of which simulation results provide an optimal mask defect printability can be selected. In some embodiments, an optimal mask defect printability can be determined by considering a trade-off between a defect printability and a number of process defects, which are not caused by a mask defect(s). While setting up lithography models with different processing conditions and selecting one lithography model providing an optimal mask defect printability have been described, it will be appreciated that embodiments using one lithography model can also be applicable. For example, one lithography model can be set up, and a process condition can be selected by observing simulated image(s) while changing a process condition gradually.

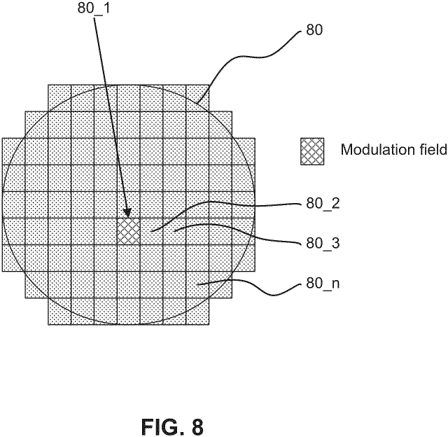

Referring back to FIG. 5, according to some embodiments of the present disclosure, exposed wafer acquirer 520 can acquire a wafer that has been exposed with a modulation condition acquired by modulation condition acquirer 510. In some embodiments, the wafer can have multiple fields having a pattern corresponding to one mask. FIG. 8 illustrates a wafer 80 having multiple fields 80_1 to 80_n, consistent with embodiments of the present disclosure. In some embodiments, multiple fields 80_1 to 80_n can be exposed with the same mask by a lithography system. In some embodiments, wafer 80 can comprise at least one field (e.g., 80_1) that is exposed with a modulation condition. In some embodiments, the rest of multiple fields (e.g., 80_2 to 80_n) can be exposed with a nominal process condition(s). In some embodiments, the rest of fields (e.g., 80_2 to 80_n) can be exposed with a process condition that can be an off-nominal condition but still can avoid creating a level of additional process defects that can burden a verification step. According to some embodiments, using a slight off-nominal process condition can further enhance a mask defect detection rate by defect verifier 540 of FIG. 5. In some embodiments, the rest of fields (e.g., 80_2 to 80_n) can be exposed with a different process condition from each other.

Referring back to FIG. 5, according to some embodiments of the present disclosure, defect identifier 530 can identify defect(s) on a first field. In some embodiments, a first field can be a modulation field 80_1 that is exposed with a modulation condition acquired by modulation condition acquirer 510. In some embodiments, defect(s) on modulation field 80_1 can be identified from an inspection image for the modulation field 80_1. In some embodiments, an inspection image is a SEM image of modulation field 80_1. In some embodiments, an inspection image can be an inspection image generated by, e.g., EBI system 100 of FIG. 3A or electron beam tool 104 of FIG. 3B. According to some embodiments of the present disclosure, defect identifier 530 can perform a full field inspection of modulation field 80_1 to find all defect(s) in the modulation field. For example, an inspection image for an entire area of modulation field 80_1 can be obtained and all defects on modulation field 80_1 can be identified. In some embodiments, defect identifier 530 can fully inspect multiple modulation fields (e.g., modulation field 80_1) to reliably find all mask defects. In some embodiments, defect(s) identified by defect identifier 530 can include mask defect(s) or process defect(s). In some embodiments, defect identifier 530 can generate a list of defect(s) associated with a corresponding location on a field or a mask.

According to some embodiments of the present disclosure, defect verifier 540 can verify defect(s) identified by defect identifier 530 whether the defect is a mask defect or not. According to some embodiments of the present disclosure, defect(s) in a list of identified defects can be verified whether the defect is a mask defect or not by inspecting a second field (e.g., 80_2 to 80_n) that is exposed with a same mask as modulation field 80_1. In some embodiments, defect verifier 540 can perform a spot inspection for location(s) for identified defect(s). For example, defect verifier 540 can inspect second field 80_2 for location(s) corresponding to location(s) of identified defect(s) of modulation field 80_1. In some embodiments, when an identified defect on modulation field 80_1 repeats on second field 80_2, the identified defect can be determined as a mask defect. When an identified defect on modulation field 80_1 does not repeat on second field 80_2, the identified defect can be determined as a non-mask defect. In some embodiments, defect verifier 540 can inspect additional field(s) to enhance accuracy of verification. For example, defect verifier 540 can inspect multiple second fields 80_2 to 80_n to verify whether the identified defect is a mask defect or not. According to some embodiments of the present disclosure, defect verifier 540 can generate a list of mask defect(s) associated with a corresponding location on a mask. In some embodiments, the list of mask defect(s) can be utilized to cure the mask defects from a corresponding mask.

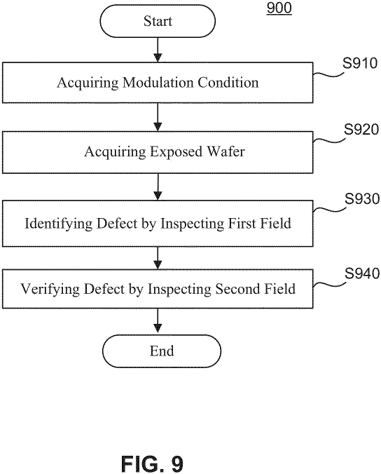

FIG. 9 is a process flowchart representing an exemplary mask defect detection method, consistent with embodiments of the present disclosure. The steps of method 900 can be performed by a system (e.g., system 500 of FIG. 5). Some steps of method 900 can be performed by a charged-particle beam inspection system (e.g., EBI system 100 of FIG. 3), or computational lithography system, or other photolithography systems. It is appreciated that the illustrated method 900 can be altered to modify the order of steps and to include additional steps.

In step S910, a modulation condition can be acquired. Step S910 can be performed by, for example, modulation condition acquirer 510, among others. In some embodiments, a modulation process can enhance a mask defect printability on the wafer when exposing a wafer (using a mask of a lithography system) with the selected modulation condition. In some embodiments, a modulation process condition can cause a mask defect(s) including an external particle(s) on a mask can more reliably be printed on a wafer, thereby improving a mask defect detection rate. In some embodiments, a modulation process condition can be different from a nominal process condition of a lithography system for exposing a wafer with a mask. According to some embodiments of the present disclosure, a process condition that can be tuned to improve a defect printability can comprise exposure dose, focus, an illumination condition, etc. of a lithography system, e.g., lithography system 10 of FIG. 1. According to some embodiments, a modulation condition can be acquired based on experimentation or simulation. The process of determining a modulation condition has been described referring to FIG. 7A and FIG. 7B, and thus the detailed explanation will be omitted here for simplicity purposes.

In step S920, an exposed wafer can be acquired. Step S920 can be performed by, for example, exposed wafer acquirer 520, among others. In some embodiments, the wafer has been exposed with a modulation condition acquired by step S910. In some embodiments, as shown in FIG. 8, wafer 80 can have multiple fields 80_1 to 80_n each of which has a pattern corresponding to one mask. In some embodiments, wafer 80 can comprise at least one field (e.g., 80_1) that is exposed with a modulation condition acquired in step S910. In some embodiments, the rest of multiple fields (e.g., 80_2 to 80_n) can be exposed with a nominal process condition(s) or slight off-nominal condition(s). In some embodiments, the rest of fields (e.g., 80_2 to 80_n) can be exposed with a different process condition from each other.

In step S930, defect(s) on a first field can be identified by inspecting a first field. Step S930 can be performed by, for example, defect identifier 530, among others. In some embodiments, a first field can be a modulation field 80_1 that is exposed with a modulation condition acquired in step S920. In some embodiments, defect(s) on modulation field 80_1 can be identified from an inspection image for the modulation field 80_1. According to some embodiments of the present disclosure, a full field inspection of modulation field 80_1 can be performed to find all defect(s) in the modulation field. In some embodiments, multiple modulation fields can be fully inspected to reliably find all mask defects. In some embodiments, a list of defect(s) associated with a corresponding location on a field or a mask can be generated.

In step S940, defect(s) can be verified by inspecting a second field. Step S940 can be performed by, for example, defect verifier 540, among others. According to some embodiments of the present disclosure, defect(s) identified in step S930 can be verified whether the defect is a mask defect or not. According to some embodiments of the present disclosure, defect(s) in a list of identified defects can be verified whether the defect is a mask defect or not by inspecting a second field (e.g., 80_2 to 80_n) that is exposed with a same mask as modulation field 80_1. In some embodiments, a spot inspection for location(s) for identified defect(s) can be performed for verification. In some embodiments, when an identified defect on modulation field 80_1 repeats on second field 80_2, the identified defect can be determined as a mask defect. When an identified defect on modulation field 80_1 does not repeat on second field 80_2, the identified defect can be determined as a non-mask defect. In some embodiments, additional field(s) can be inspected to enhance accuracy of verification. For example, multiple second fields 80_2 to 80_n can be inspected to verify whether the identified defect is a mask defect or not. According to some embodiments of the present disclosure, a list of mask defect(s) associated with a corresponding location on a mask can be generated. In some embodiments, the list of mask defect(s) can be utilized to cure the mask defects from a corresponding mask.

A non-transitory computer readable medium may be provided that stores instructions for a processor of a controller (e.g., controller 109 of FIG. 1) to carry out, among other things, image inspection, image acquisition, stage positioning, beam focusing, electric field adjustment, beam bending, condenser lens adjusting, activating charged-particle source, beam deflecting, and at least some steps of methods 710, 720, and 900. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:
1. A method comprising:
   inspecting an exposed wafer after the wafer was exposed, by a lithography system using a mask, with a selected process condition that is determined based on a mask defect printability under the selected process condition; and
   identifying, based on the inspection, a wafer defect that is caused by a defect on the mask to enable identification of the defect on the mask.
2. The method of clause 1, wherein the exposed wafer comprises a first field and a second field, the first field being exposed with the selected process condition and the second field being exposed with a different process condition from the selected process condition.
3. The method of clause 2, wherein identifying the wafer defect comprises: inspecting an entire area of the first field to identify a defect on the first field.
4. The method of clause 2 or 3, wherein identifying the wafer defect further comprises: inspecting the second field at a location corresponding to a location of the identified defect on the first field.
5. The method of any one of clauses 1-4, further comprising: exposing, by a lithography system using the mask, each of multiple fields of a test wafer with a different process condition;
   inspecting a plurality of the multiple fields of the test wafer to identify a defect on a corresponding field; and
   determining the selected process condition based on the inspection.
6. The method of clause 5, wherein determining the selected process condition comprises:
   selecting a field that meets a criterion among the multiple fields, the criterion being a predetermined range of a number of defects identified in the corresponding field;
   determining a process condition used to expose the selected field to be the selected process condition.
7. The method of clause 5 or 6, wherein inspecting the plurality of the multiple fields of the test wafer comprises:
   inspecting a partial area of a field of the multiple fields to identify a defect on the partial area.
8. The method of any one of clauses 1-4, further comprising:
   setting a lithography model for simulating an exposure process of the wafer with the mask having a defect particle;
   simulating an electromagnetic field near the mask based on topography of the mask and the defect particle on the mask, the electromagnetic field enabling a determination of a light path near the mask; simulating an aerial image or resist image based on the simulated electromagnetic field at the wafer; and
   determining the selected process condition for the lithography system based on the simulated aerial image or resist image.
9. The method of clause 8, wherein setting up the lithography model comprises:
   setting a plurality of lithography models with a different processing condition.
10. The method of any one of clauses 1-9, wherein the process condition comprises exposure dose, focus, or an illumination condition.
11. The method of any one of clauses 1-9, wherein the selected process condition comprises exposure dose less than a nominal dose.
12. The method of clause 11, wherein the nominal dose is associated with a production process condition.
13. The method of any one of clauses 1-12, further comprising: exposing the wafer, by the lithography system using the mask, with the selected process condition.
14. A method for determining a modulation condition, comprising:
   inspecting a plurality of multiple fields of a test wafer to identify a defect on a corresponding field after each of the multiple fields of the test wafer was exposed, by a lithography system using a mask, with a different process condition; and
   determining a modulation condition based on the inspection.
15. The method of clause 14, wherein determining the modulation condition comprises:
   selecting a field that meets a criterion among the multiple fields, the criterion being a predetermined range of a number of defects identified in the corresponding field;
   determining a process condition used to expose the selected field to be the modulation condition.
16. The method of clause 14 or 15, wherein inspecting the plurality of the multiple fields of the test wafer comprises:
   inspecting a partial area of a field of the multiple fields to identify a defect on the partial area.
17. The method of any one of clauses 14 to 16, further comprising:
   exposing a wafer by a lithography system using the mask, wherein the exposed wafer comprises a first field and a second field, the first field being exposed with the modulation condition and the second field being exposed with a nominal process condition different from the modulation condition.
18. The method of any one of clauses 14-17, wherein the process condition comprises exposure dose, focus, or an illumination condition.
19. The method of any one of clauses 14 to 18, further comprising:
   exposing, by the lithography system using the mask, each of the multiple fields of the test wafer with a different process condition.
20. A method for determining a modulation condition, comprising:
   setting a lithography model for simulating an exposure process of a wafer with a mask having a defect particle;
   simulating an electromagnetic field near the mask based on topography of the mask and the defect particle on the mask, the electromagnetic field enabling a determination of a light path near the mask; simulating an aerial image or resist image based on the simulated electromagnetic field at the wafer; and
   determining a modulation condition for a lithography system based on the simulated aerial image or resist image.
21. The method of clause 20, wherein setting up the lithography model comprises:
   setting a plurality of lithography models with a different processing condition.
22. The method of clause 20, wherein determining the modulation condition comprises: determining the modulation condition by observing the simulated aerial image or resist image while changing a process condition.
23. The method of any one of clauses 20-22, further comprising:
   exposing a wafer by a lithography system using the mask, wherein the exposed wafer comprises a first field and a second field, the first field being exposed with the modulation condition and the second field being exposed with a nominal process condition different from the modulation condition.
24. The method of any one of clauses 20-23, wherein the process condition comprises exposure dose, focus, or an illumination condition.
25. A charged particle beam device configured to inspect a wafer exposed by a lithography system using a mask, comprising:
   a charged particle beam source configured to irradiate a first field and a second field of the wafer, the first field being exposed with a first process condition and the second field being exposed with a second process condition that is different from the first process condition;
   a detector configured to collect secondary charged particles emitted from the wafer that enable identification of a defect on the wafer, wherein the first field and the second field comprise a different number of defects on the corresponding field from each other; and
   a processor configured to facilitate a determination of a process condition to use to inspect a second mask based on mask defect printability, the mask defect printability being determined based on the identified defects.
26. The device of clause 25, wherein the first process condition is different from the second process condition in exposure dose, focus, or an illumination condition.
27. The device of clause 25 or 26, wherein the first process condition comprises exposure dose less than a nominal exposure dose.
28. The device of any one of clauses 25-27, wherein the second process condition is a nominal process condition.
29. The device of any one of clauses 25-28, wherein the charged particle beam source is configured to irradiate an entire area of the first field to identify a defect on the first field and to irradiate the second field at a location corresponding to a location of the identified defect on the first field.
30. An apparatus comprising:
   a memory storing a set of instructions; and
   at least one processor configured to execute the set of instructions to cause the apparatus to perform: inspecting an exposed wafer after the wafer was exposed, by a lithography system using a mask, with a selected process condition that is determined based on a mask defect printability under the selected process condition; and
   identifying, based on the inspection, a wafer defect that is caused by a defect on the mask to enable identification of the defect on the mask.
31. The apparatus of clause 30, wherein the exposed wafer comprises a first field and a second field, the first field being exposed with the selected process condition and the second field being exposed with a different process condition from the selected process condition.
32. The apparatus of clause 31, wherein, in identifying the wafer defect, the at least one processor is configured to execute the set of instructions to cause the apparatus to perform:
   inspecting an entire area of the first field to identify a defect on the first field.
33. The apparatus of clause 31 or 32, wherein, in identifying the wafer defect, the at least one processor is configured to execute the set of instructions to cause the apparatus to perform:
   inspecting the second field at a location corresponding to a location of the identified defect on the first field.
34. The apparatus of any one of clauses 30-33, wherein the at least one processor is configured to execute the set of instructions to cause the apparatus to further perform:
   inspecting a plurality of multiple fields of a test wafer to identify a defect on a corresponding field after each of the multiple fields of the test wafer was exposed, by a lithography system using a mask, with a different process condition; and
   determining the selected process condition based on the inspection.
35. The apparatus of clause 34, wherein, in determining the selected process condition, the at least one processor is configured to execute the set of instructions to cause the apparatus to further perform: selecting a field that meets a criterion among the multiple fields, the criterion being a predetermined range of a number of defects identified in the corresponding field;
   determining a process condition used to expose the selected field to be the selected process condition.
36. The apparatus of clause 34 or 35, wherein, in inspecting the plurality of the multiple fields of the test wafer, the at least one processor is configured to execute the set of instructions to cause the apparatus to perform:
   inspecting a partial area of a field of the multiple fields to identify a defect on the partial area.
37. The apparatus of any one of clauses 30-33, wherein the at least one processor is configured to execute the set of instructions to cause the apparatus to further perform:
   setting a lithography model for simulating an exposure process of the wafer with the mask having a defect particle;
   simulating an electromagnetic field near the mask based on topography of the mask and the defect particle on the mask, the electromagnetic field enabling a determination of a light path near the mask; simulating an aerial image or resist image based on the simulated electromagnetic field at the wafer; and
   determining the selected process condition for the lithography system based on the simulated aerial image or resist image.
38. The apparatus of clause 37, wherein, in setting up the lithography model, the at least one processor is configured to execute the set of instructions to cause the apparatus to further perform: setting a plurality of lithography models with a different processing condition.
39. The apparatus of any one of clauses 30-38, wherein the process condition comprises exposure dose, focus, or an illumination condition.
40. The apparatus of any one of clause 30-39, wherein the selected process condition comprises exposure dose less than a nominal dose.
41. An apparatus for determining a modulation condition, comprising:
   a memory storing a set of instructions; and
   at least one processor configured to execute the set of instructions to cause the apparatus to perform: inspecting a plurality of multiple fields of a test wafer to identify a defect on a corresponding field after each of the multiple fields of the test wafer was exposed, by a lithography system using a mask, with a different process condition; and
   determining a modulation condition based on the inspection.
42. The apparatus of clause 41, wherein, in determining the modulation condition, the at least one processor is configured to execute the set of instructions to cause the apparatus to further perform: selecting a field that meets a criterion among the multiple fields, the criterion being a predetermined range of a number of defects identified in the corresponding field;
   determining a process condition used to expose the selected field to be the modulation condition.
43. The apparatus of clause 41 or 42, wherein, in inspecting the plurality of the multiple fields of the test wafer, the at least one processor is configured to execute the set of instructions to cause the apparatus to perform:
   inspecting a partial area of a field of the multiple fields to identify a defect on the partial area.
44. The apparatus of any one of clauses 41-43, wherein the process condition comprises exposure dose, focus, or an illumination condition.
45. An apparatus for determining a modulation condition, comprising:
   a memory storing a set of instructions; and
   at least one processor configured to execute the set of instructions to cause the apparatus to perform: setting a lithography model for simulating an exposure process of a wafer with a mask having a defect particle;
   simulating an electromagnetic field near the mask based on topography of the mask and the defect particle on the mask, the electromagnetic field enabling a determination of a light path near the mask; simulating an aerial image or resist image based on the simulated electromagnetic field at the wafer; and
   determining a modulation condition for a lithography system based on the simulated aerial image or resist image.
46. The apparatus of clause 45, wherein, in setting up the lithography model, the at least one processor is configured to execute the set of instructions to cause the apparatus to further perform wherein setting up the lithography model comprises:
   setting a plurality of lithography models with a different processing condition.
47. The apparatus of clause 45, wherein, in determining the modulation condition, the at least one processor is configured to execute the set of instructions to cause the apparatus to further perform: determining the modulation condition by observing the simulated aerial image or resist image while changing a process condition.
48. The apparatus of any one of clauses 45-47, wherein the process condition comprises exposure dose, focus, or an illumination condition.
49. A non-transitory computer readable medium that stores a set of instructions that is executable by at least on processor of a computing device to cause the computing device to perform a method comprising:
   inspecting an exposed wafer after the wafer was exposed, by a lithography system using a mask, with a selected process condition that is determined based on a mask defect printability under the selected process condition; and
   identifying, based on the inspection, a wafer defect that is caused by a defect on the mask to enable identification of the defect on the mask.
50. The computer readable medium of clause 49, wherein the exposed wafer comprises a first field and a second field, the first field being exposed with the selected process condition and the second field being exposed with a different process condition from the selected process condition.
51. The computer readable medium of clause 50, wherein, in identifying the wafer defect, the set of instructions that is executable by at least one processor of the computing device cause the computing device to further perform:
   inspecting an entire area of the first field to identify a defect on the first field.
52. The computer readable medium of clause 50 or 51, wherein, in identifying the wafer defect, the set of instructions that is executable by at least one processor of the computing device cause the computing device to further perform:
   inspecting the second field at a location corresponding to a location of the identified defect on the first field.
53. The computer readable medium of any one of clauses 49-52, wherein the set of instructions that is executable by at least one processor of the computing device cause the computing device to further perform:
   inspecting a plurality of multiple fields of a test wafer to identify a defect on a corresponding field after each of the multiple fields of the test wafer was exposed, by a lithography system using a mask, with a different process condition; and
   determining the selected process condition based on the inspection.
54. The computer readable medium of clause 53, wherein, in determining the selected process condition, the set of instructions that is executable by at least one processor of the computing device cause the computing device to further perform:
   selecting a field that meets a criterion among the multiple fields, the criterion being a predetermined range of a number of defects identified in the corresponding field;
   determining a process condition used to expose the selected field to be the selected process condition.
55. The computer readable medium of clause 53 or 54, wherein, in inspecting the plurality of the multiple fields of the test wafer, the set of instructions that is executable by at least one processor of the computing device cause the computing device to further perform:
   inspecting a partial area of a field of the multiple fields to identify a defect on the partial area.
56. The computer readable medium of any one of clauses 49-52, wherein the set of instructions that is executable by at least one processor of the computing device cause the computing device to further perform:
   setting a lithography model for simulating an exposure process of the wafer with the mask having a defect particle;
   simulating an electromagnetic field near the mask based on topography of the mask and the defect particle on the mask, the electromagnetic field enabling a determination of a light path near the mask;
   simulating an aerial image or resist image based on the simulated electromagnetic field at the wafer; and
   determining the selected process condition for the lithography system based on the simulated aerial image or resist image.
57. The computer readable medium of clause 56, wherein, in setting up the lithography model, the set of instructions that is executable by at least one processor of the computing device cause the computing device to further perform:
   setting a plurality of lithography models with a different processing condition.
58. The computer readable medium of any one of clauses 49-57, wherein the process condition comprises exposure dose, focus, or an illumination condition.
59. The computer readable medium of any one of clauses 49-57, wherein the selected process condition comprises exposure dose less than a nominal dose.
60. A non-transitory computer readable medium that stores a set of instructions that is executable by at least on processor of a computing device to cause the computing device to perform a method for determining a modulation condition, the method comprising:
   inspecting a plurality of multiple fields of a test wafer to identify a defect on a corresponding field after each of the multiple fields of the test wafer was exposed, by a lithography system using a mask, with a different process condition; and
   determining a modulation condition based on the inspection.
61. The computer readable medium of clause 60, wherein, in determining the modulation condition, the set of instructions that is executable by at least one processor of the computing device cause the computing device to further perform:
   selecting a field that meets a criterion among the multiple fields, the criterion being a predetermined range of a number of defects identified in the corresponding field;
   determining a process condition used to expose the selected field to be the modulation condition.
62. The computer readable medium of clause 60 or 61, wherein, in inspecting the plurality of the multiple fields of the test wafer, the set of instructions that is executable by at least one processor of the computing device cause the computing device to further perform:
   inspecting a partial area of a field of the multiple fields to identify a defect on the partial area.
63. The computer readable medium of any one of clauses 60-62, wherein the process condition comprises exposure dose, focus, or an illumination condition.
64. A non-transitory computer readable medium that stores a set of instructions that is executable by at least on processor of a computing device to cause the computing device to perform a method for determining a modulation condition, the method comprising:
   setting a lithography model for simulating an exposure process of a wafer with a mask having a defect particle;
   simulating an electromagnetic field near the mask based on topography of the mask and the defect particle on the mask, the electromagnetic field enabling a determination of a light path near the mask; simulating an aerial image or resist image based on the simulated electromagnetic field at the wafer; and
   determining a modulation condition for a lithography system based on the simulated aerial image or resist image.
65. The computer readable medium of clause 64, wherein, in setting up the lithography model, the set of instructions that is executable by at least one processor of the computing device cause the computing device to further perform:
   setting a plurality of lithography models with a different processing condition.
66. The computer readable medium of clause 64, wherein, in determining the modulation condition, the set of instructions that is executable by at least one processor of the computing device cause the computing device to further perform:
   determining the modulation condition by observing the simulated aerial image or resist image while changing a process condition.
67. The computer readable medium of any one of clauses 64-66, wherein the process condition comprises exposure dose, focus, or an illumination condition.
68. The method of clauses 5, 14, or 19, wherein the multiple fields of the test wafer are a subset of all fields of the test wafer, the subset being less than all the fields.
69. The device of clause 25, wherein the mask and the second mask are a same single mask.

Block diagrams in the figures may illustrate the architecture, functionality, and operation of possible implementations of systems, methods, and computer hardware or software products according to various exemplary embodiments of the present disclosure. In this regard, each block in a schematic diagram may represent certain arithmetical or logical operation processing that may be implemented using hardware such as an electronic circuit. Blocks may also represent a module, segment, or portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. An apparatus comprising:
a memory storing a set of instructions; and
at least one processor configured to execute the set of instructions to cause the apparatus to perform:
inspecting an exposed wafer after the wafer was exposed, by a lithography system using a mask, with a selected process condition that is determined based on a mask defect printability under the selected process condition; and
identifying, based on the inspection, a wafer defect that is caused by a defect on the mask to enable identification of the defect on the mask.

2. The apparatus of claim 1, wherein the exposed wafer comprises a first field and a second field, the first field being exposed with the selected process condition and the second field being exposed with a different process condition from the selected process condition.

3. The apparatus of claim 2, wherein, in identifying the wafer defect, the at least one processor is configured to execute the set of instructions to cause the apparatus to perform:
inspecting an entire area of the first field to identify a defect on the first field.

4. The apparatus of claim 2, wherein, in identifying the wafer defect, the at least one processor is configured to execute the set of instructions to cause the apparatus to perform:
inspecting the second field at a location corresponding to a location of the identified defect on the first field.

5. The apparatus of claim 1, wherein the at least one processor is configured to execute the set of instructions to cause the apparatus to further perform:
inspecting a plurality of multiple fields of a test wafer to identify a defect on a corresponding field after each of the multiple fields of the test wafer was exposed, by a lithography system using a mask, with a different process condition; and
determining the selected process condition based on the inspection.

6. The apparatus of claim 5, wherein, in determining the selected process condition, the at least one processor is configured to execute the set of instructions to cause the apparatus to further perform:
selecting a field that meets a criterion among the multiple fields, the criterion being a predetermined range of a number of defects identified in the corresponding field;
determining a process condition used to expose the selected field to be the selected process condition.

7. The apparatus of claim 5, wherein, in inspecting the plurality of the multiple fields of the test wafer, the at least one processor is configured to execute the set of instructions to cause the apparatus to perform:
inspecting a partial area of a field of the multiple fields to identify a defect on the partial area.

8. The apparatus of claim 1, wherein the at least one processor is configured to execute the set of instructions to cause the apparatus to further perform:
setting a lithography model for simulating an exposure process of the wafer with the mask having a defect particle;
simulating an electromagnetic field near the mask based on topography of the mask and the defect particle on the mask, the electromagnetic field enabling a determination of a light path near the mask;
simulating an aerial image or resist image based on the simulated electromagnetic field at the wafer; and
determining the selected process condition for the lithography system based on the simulated aerial image or resist image.

9. The apparatus of claim 8, wherein, in setting up the lithography model, the at least one processor is configured to execute the set of instructions to cause the apparatus to further perform:
setting a plurality of lithography models with a different processing condition.

10. The apparatus of claim 1, wherein the process condition comprises exposure dose, focus, or an illumination condition.

11. The apparatus of claim 1, wherein the selected process condition comprises exposure dose less than a nominal dose.

12. A non-transitory computer readable medium that stores a set of instructions that is executable by at least one processor of a computing device to cause the computing device to perform a method for determining a modulation condition, the method comprising:
inspecting a plurality of multiple fields of a test wafer to identify a defect on a corresponding field after each of the multiple fields of the test wafer was exposed, by a lithography system using a mask, with a different process condition; and
determining a modulation condition based on the inspection.

13. The computer readable medium of claim 12, wherein, in determining the modulation condition, the set of instructions that is executable by at least one processor of the computing device cause the computing device to further perform:
selecting a field that meets a criterion among the multiple fields, the criterion being a predetermined range of a number of defects identified in the corresponding field;
determining a process condition used to expose the selected field to be the modulation condition.

14. The computer readable medium of claim 12, wherein, in inspecting the plurality of the multiple fields of the test wafer, the set of instructions that is executable by at least one processor of the computing device cause the computing device to further perform:
inspecting a partial area of a field of the multiple fields to identify a defect on the partial area.

15. The computer readable medium of claim 12, wherein the process condition comprises exposure dose, focus, or an illumination condition.
